(19) United States
(12) Patent Application Publication
(10) Pub. No.: US 2025/0220818 A1
(43) Pub. Date: Jul. 3, 2025

(54) FLOW ENHANCED DUMMY STRUCTURE TO ENABLE CAPILLARY FLOW BASED SIDEWALL FILLING

(71) Applicant: Intel Corporation, Santa Clara, CA (US)

(72) Inventors: Bohan SHAN, Chandler, AZ (US); Wei LI, Chandler, AZ (US); Jose WAIMIN, Gilbert, AZ (US); Ryan CARRAZZONE, Chandler, AZ (US); Kyle ARRINGTON, Gilbert, AZ (US); Ziyin LIN, Chandler, AZ (US); Hongxia FENG, Chandler, AZ (US); Yiqun BAI, Chandler, AZ (US); Haobo CHEN, Chandler, AZ (US); Dingying David XU, Chandler, AZ (US); Yongki MIN, Phoenix, AZ (US); Clay ARRINGTON, Queen Creek, AZ (US); Srinivas Venkata Ramanuja PIETAMBARAM, Chandler, AZ (US); Gang DUAN, Chandler, AZ (US); Xiaoying GUO, Chandler, AZ (US)

(21) Appl. No.: 18/397,226

(22) Filed: Dec. 27, 2023

(51) Int. Cl. H05K 1/18; H01L 21/48; H01L 23/498; H01L 25/16

(52) U.S. Cl. CPC H05K 1/185; H01L 21/481; H01L 23/49827; H01L 25/16; H05K 2201/10015; H05K 2201/10022; H05K 2201/1003

(57) ABSTRACT

Embodiments disclosed herein include an apparatus with a component embedded in a core. Apparatuses disclosed herein may comprise a first component with a first surface and a second surface opposite from the first surface, where a pad is provided on the first surface. In an embodiment, a layer is over the second surface of the first component, and a second component is over the layer. In an embodiment, the second component comprises a hole that passes through at least a partial thickness of the second component.

### BACKGROUND

As advanced packaging is enabling more aggressive computation capability, high power and high quality power delivery is needed to support all of the overlying chiplets. Accordingly, the ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Accordingly, placing such passive components in deep cavities through the core can be problematic. For example, the passive components may shift or rotate during embedding. Additionally, filling the small gaps between sidewalls of the cavity and the sidewall of the passive component is difficult. Voids may be present, which can lead to reliability issues for the electronic package.

### BRIEF DESCRIPTION OF THE DRAWINGS

FIG. 1A is a cross-sectional illustration of a core with an embedded passive component that has shifted during the embedding process, in accordance with an embodiment.

FIG. 1B is a cross-sectional illustration of a core with an embedded passive component that has voids between the sidewall of the passive component and the sidewall of the cavity, in accordance with an embodiment.

FIG. 2A is a cross-sectional illustration of a core with an embedded passive component that comprises an overlying dummy structure with internal fluidic paths, in accordance with an embodiment.

FIG. 2B is a perspective view illustration of the dummy structure with internal fluidic paths, in accordance with an embodiment.

FIG. 2C is a cross-sectional illustration of the dummy structure that shows the horizontal fluidic paths, in accordance with an embodiment.

FIG. 3A is a cross-sectional illustration of a core with an embedded passive component that comprises an overlying dummy structure with a vertical fluidic path and an adhesive with horizontal fluidic paths, in accordance with an embodiment.

FIG. 3B is a plan view illustration of the dummy structure with a vertical fluidic path, in accordance with an embodiment.

FIG. 3C is a plan view illustration of the adhesive layer with fluidic paths over the passive component, in accordance with an embodiment.

FIGS. 4A-4D are cross-sectional illustrations depicting a process for embedding a passive component in a core, in accordance with an embodiment.

FIG. 4E is a process flow diagram of a process for assembling a component in a core with an integrated fluidic path in a dummy structure, in accordance with an embodiment.

FIG. 5A is a cross-sectional illustration of a core with a plurality of passive components embedded in a single cavity, in accordance with an embodiment.

FIG. 5B is a cross-sectional illustration of a core with a plurality of passive components with different thicknesses embedded in a single cavity, in accordance with an embodiment.

FIG. 6 is a cross-sectional illustration of a package substrate with a passive component embedded in a core, in accordance with an embodiment.

FIG. 7 is a cross-sectional illustration of an electronic system with a package substrate that includes an embedded passive component and dummy structure with fluidic paths, in accordance with an embodiment.

FIG. 8 is a schematic of a computing device built in accordance with an embodiment.

### EMBODIMENTS OF THE PRESENT DISCLOSURE

Described herein are electronic systems, and more particularly, dummy structures with integrated flow paths for improved sidewall filling, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

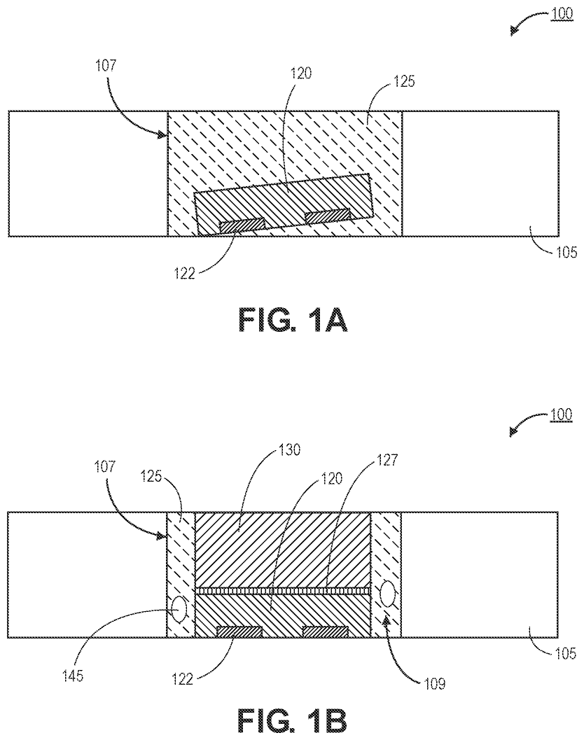

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIGS. 1A and 1B.

Referring now to FIG. 1A, a cross-sectional illustration of a portion of a package substrate 100 is shown, in accordance with an embodiment. The package substrate 100 may comprise a core 105. The core 105 may be a glass core, an organic core, or the like. In an embodiment, a cavity 107 passes at least partially through the core 105. For example, in FIG. 1A the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. As shown, the component 120 has tilted so that one side is raised up from the bottom of the core 105. This may make it difficult to make electrical contact to the pads 122 that are at the bottom of the component 120 in subsequent processing operations.

In order to combat the shifting of the component 120, a dummy structure 130 may be added, as shown in FIG. 1B. In an embodiment, the dummy structure 130 is adhered to the component 120 by a layer 127, such as an adhesive material. The dummy structure 130 may provide additional thickness to the component 120 so that the combined thickness is substantially equal to the thickness of the core 105. However, increasing the total thickness of the component 120 and dummy structure 130 device leads to high aspect ratio gaps 109 between sidewalls of the device and the sidewalls of the cavity 107. These high aspect ratio gaps 109 are difficult to fill with traditional filling processes. As such, voids 145 may be generated in the gaps 109. The voids 145 can lead to reliability issues for the package substrate 100.

Accordingly, embodiments disclosed herein aim to provide devices with thicknesses that substantially match the thickness of the core 105, while still enabling complete fill of the gaps 109. In one embodiment, this combination can be enabled through the use of a dummy structure 130 that comprises internal fluidic paths. The internal fluidic paths may divert incoming fill layer 125 material horizontally out a sidewall of the dummy structure 130. This provides a larger flow of material into the gaps 109 and prevents void 145 formation. In another embodiment, the lateral flow may be directed by channels that are defined by the layer 127. A vertical hole through the dummy structure may fluidically couple to the lateral channels in the layer 127 to allow for improved filling of the gaps 109.

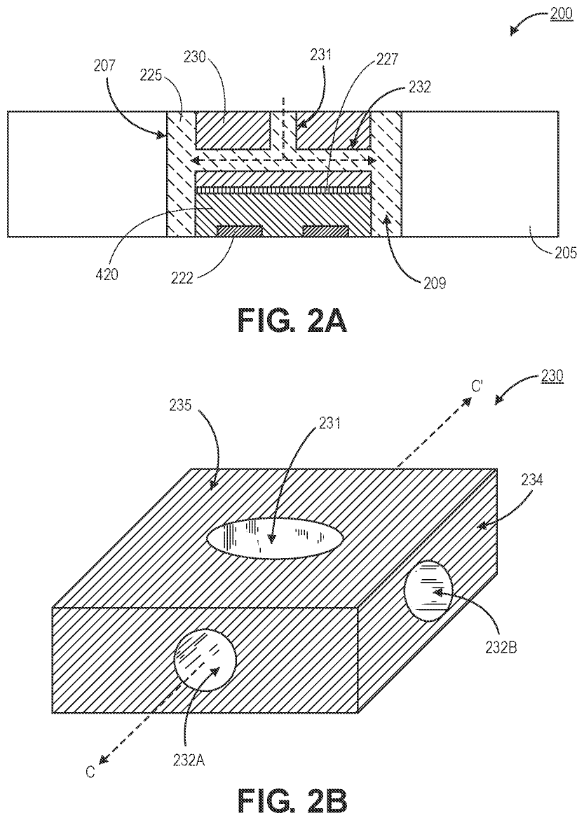

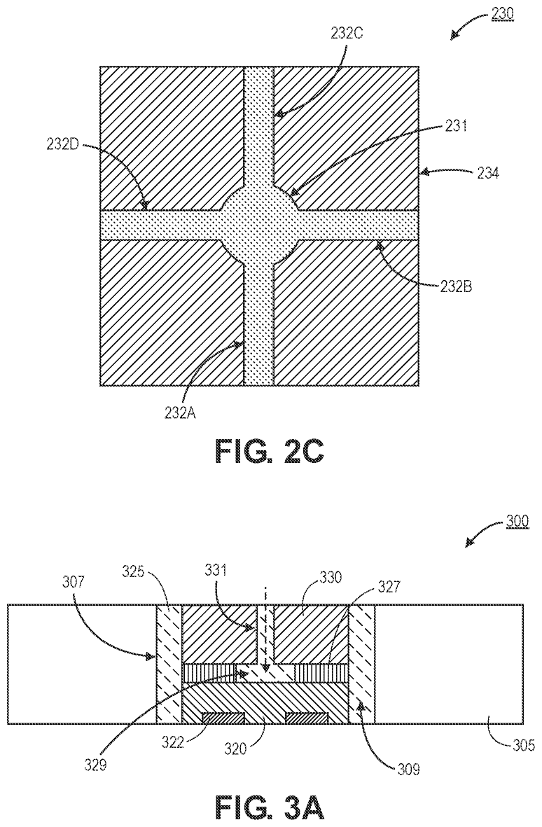

Referring now to FIG. 2A, a cross-sectional illustration of a portion of a package substrate 200 is shown, in accordance with an embodiment. The package substrate 200 may comprise a core 205. The core 205 may comprise any suitable core material, such as a glass core or an organic core with embedded fibers. In the case of a glass core 205, the core 205 may be substantially all glass. The core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 205 may be distinguished from, for example, the “prepreg” or “RF4” core of a Printed Circuit Board (PCB) substrate which typically comprises glass fibers embedded in a resinous organic material, such as an epoxy. The core 205 may have any suitable dimensions. In a particular embodiment, the core 205 may have a thickness that is approximately 50 μm or greater. For example, the thickness of the core 205 may be between approximately 50 μm and approximately 1.4 mm. Though, smaller or larger thicknesses may also be used. The core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 205 (from an overhead plan view) may be between approximately 10 mm×10 mm and approximately 250 mm×250 mm. In an embodiment, the core 205 may have a first side that is perpendicular or orthogonal to a second side. In a more general embodiment, the core 205 may comprise a rectangular prism volume with sections (e.g., vias) removed and filled with other materials (e.g., metal, etc.).

The core 205 may comprise a single monolithic layer of glass. In other embodiments, the core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 205 may each have a thickness less than approximately 50 μm. For example, discrete layers of glass in the core 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The core 205 may be any suitable glass formulation that has the necessary mechanical robustness and compatibility with semiconductor packaging manufacturing and assembly processes. For example, the core 205 may comprise aluminosilicate glass, borosilicate glass, alumino-borosilicate glass, silica, fused silica, or the like. In some embodiments, the core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 205 may comprise at least 23 percent silicon (by weight) and at least 26 percent oxygen (by weight). In some embodiments, the core 205 may further comprise at least 5 percent aluminum (by weight).

In an embodiment, a cavity 207 may be provided at least partially through a thickness of the core 205. In the illustrated embodiment, the cavity 207 passes entirely through the thickness of the core 205. The cavity 207 may have substantially vertical sidewalls. In other embodiments, the cavity 207 may have sloped or otherwise tapered sidewalls. For example, a top of the cavity 207 may be wider than a bottom of the cavity 207 in some embodiments.

In an embodiment, a component 220 is inserted into the cavity 207. The component 220 may comprise an electrical component. More particularly, the component 220 may be a passive electrical component, such as an inductor, a capacitor, a resistor, or the like. The component 220 may be formed on a substrate, such as a semiconductor substrate (e.g., silicon). For example, a deep trench capacitor (DTC) may include capacitive plates that fill trenches formed into a surface of a silicon substrate. The component 220 may have pads 222 on a surface exposed at the bottom of the core 205 (as shown in FIG. 2A). The pads 222 may be substantially coplanar with the bottom of the core 205. As used herein “substantially coplanar” may refer to two surfaces that are within approximately 10 μm of being coplanar with each other.

In an embodiment, the component 220 may have a thickness that is less than a thickness of the core 205. For example, the thickness of the component 220 may be up to approximately 50 μm smaller than the thickness of the core 205, up to approximately 200 μm smaller than the thickness of the core 205, up to approximately 500 μm smaller than the thickness of the core 205, up to approximately 1 mm smaller than the thickness of the core 205, or any other difference in thickness. In an embodiment, the component 220 may have a thickness that is up to 90% of a thickness of the core 205, up to approximately 50% of the thickness of the core 205, or up to approximately 15% of the thickness of the core 205.

In an embodiment, a layer 227 is applied over a top surface of the component 220. The layer 227 may be an adhesive material in some embodiments. The layer 227 may be used to mechanically couple a dummy structure 230 (sometimes referred to as a “dummy component” or a “component”) to the component 220. The dummy structure 230 provides additional thickness to the component 220 so that a combined thickness of the stack (i.e., the combination of a thickness of the component 220, a thickness of the layer 227, and a thickness of the dummy structure 230) is approximately equal to the thickness of the core 205. Approximately equal thicknesses may refer to thicknesses that are within 10% of each other. Though, it is to be appreciated that closely matching the thicknesses may provide improved assembly and integration processes.

In an embodiment, the dummy structure 230 may also comprise fluidic paths that are integrated into the dummy structure 230. The fluidic paths may comprise one or more holes 231 that pass at least partially through a thickness of the dummy structure 230. In an embodiment, one or more openings 232 may intersect the hole 231. The fluidically coupled hole 231 and openings 232 may fluidically couple a top of the dummy structure 230 to a sidewall of the dummy structure 230. As indicated by the dashed arrows, fill layer 225 can pass down into the hole 231 and out the openings 232 into the gap 209 between the stack and the sidewall of the cavity 207. As such, improved filling of high aspect ratio features can be provided since material is pumped into the gap 209 at a greater depth into the cavity 207. In some embodiments, the gap 209 may have a width that is up to approximately 100 μm, up to approximately 50 μm, or up to approximately 25 μm. Though, embodiments with wider gaps 209 may also benefit from embodiments disclosed herein.

As used herein, “fluidically coupled” or “fluidic coupling” may refer to the ability to transfer a fluid (e.g., a liquid or gas) between the two points, locations, regions, etc. that are fluidically coupled together. For example, a hole 231 may be fluidically coupled to an opening 232 when a fluid that flows through the hole 231 can be transferred to the opening 232 so that the fluid can flow through the opening 232. Fluidic coupling may refer to features that are directly connected to each other, and/or fluidic coupling may refer to features that are connected to each other through one or more intervening structures.

Further, it is to be appreciated that the holes 231 and/or the openings 232 may be at least partially filled by the fill layer 225. That is, when looking at a cross-section of the core 205, the dummy structure 230 may comprise regions that are filled with a second material (i.e., the fill layer 225). More particularly, while the holes 231 and/or the openings 232 are sometimes referred to as “fluidic paths”, fluids may not be capable of flowing through the holes 231 and/or the openings 232 since they may be filled with a solid material (i.e., the fill layer 225).

In an embodiment, the hole 231 may be substantially vertical. That is, a centerline of the hole 231 may be substantially orthogonal to a top surface of the dummy structure 230. As used herein, “substantially orthogonal” may refer to lines and/or planes that are within 15° of being orthogonal to each other. While hole 231 in FIG. 2A is shown as being substantially vertical, embodiments are not limited to such configurations. Similarly, the openings 232 may be substantially horizontal. That is, a centerline of the openings 232 may be substantially orthogonal to a sidewall surface of the dummy structure 230. While openings 232 in FIG. 2A are shown as being substantially horizontal, embodiments are not limited to such configurations.

In an embodiment, the dummy structure 230 may be any suitable material. In one embodiment, the dummy structure 230 comprises a dielectric material, such as a mold material, an epoxy, a polymer, or the like. In some embodiments, the dummy structure 230 may be fabricated with an injection molding process that is capable of fabricating the holes 231 and openings 232 during the molding process. 3D printing approaches may also be used to form the dummy structure 230. Alternatively, a solid block may be formed, and the holes 231 and openings 232 may be formed with a drilling process or the like. Other materials that may be suitable for the dummy structure 230 may include a metallic material, silicon, a glass material, a ceramic material, or the like.

Referring now to FIG. 2B, a perspective view illustration of the dummy structure 230 is shown, in accordance with an embodiment. As shown, the dummy structure 230 may include a top surface 235 and sidewall surfaces 234. The hole 231 may be formed into the top surface 235. The hole 231 is shown as being circular, but the hole 231 may have any suitable shape. Additionally, a plurality of holes 231 may be formed into the top surface 235 in some embodiments.

In an embodiment, openings 232 may extend into the dummy structure 230 through the sidewall surfaces 234. For example, opening 232A is on a first sidewall 234, and opening 232B is on a second sidewall 234. While one opening 232 is shown on each sidewall 234, it is to be appreciated that two or more openings 232 may be provided on a single sidewall 234. Additional openings (not visible) may be provided on the sidewalls 234 that are hidden from view in FIG. 2B.

The openings 232 are shown as being circular, but the openings 232 may have any suitable shape. In one embodiment, a diameter of the hole 231 is different than diameters of the openings 232. For example, the openings 232 may have a smaller diameter than the hole 231. In an embodiment, the openings 232 intersect the hole 231. As such, a fluidic path may have a first end at a top surface 235 of the dummy structure 230 and a second end at a sidewall surface 234 of the dummy structure 230. Further, the fluidic path may have a single first end, and a plurality of second ends. That is, a single hole 231 may be fluidically coupled to a plurality of openings 232.

Referring now to FIG. 2C, a cross-sectional illustration of the dummy structure 230 along the line C-C′ in FIG. 2B is shown, in accordance with an embodiment. As shown, the cross-sectional plane is through the level of the openings 232. For example, there are four openings 232A-232D. Each opening extends out to a different sidewall 234. In an embodiment, the openings 232 may each intersect with the hole 231. That is, the fluidic path may be a one-to-many configuration (i.e., one hole 231 to a plurality of openings 232). In other embodiments, the fluidic path (or fluidic paths) may be a one-to-one configuration (i.e., one hole 231 to one opening 232).

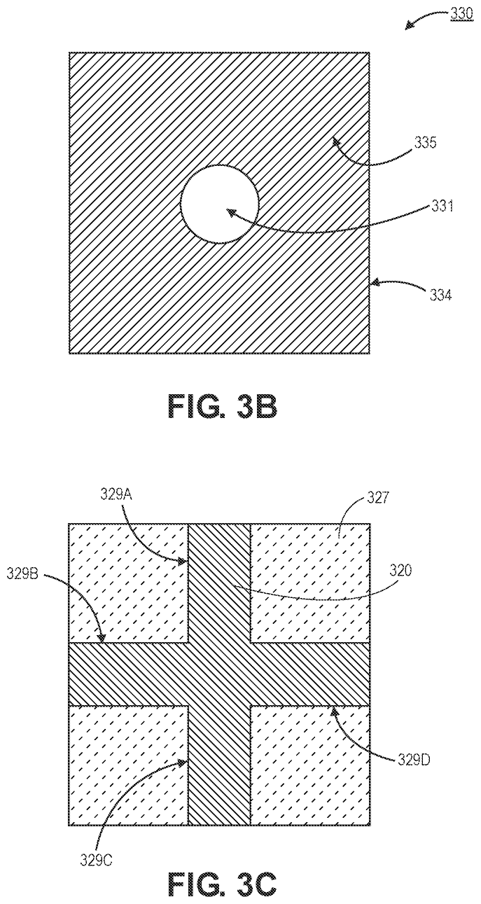

Referring now to FIGS. 3A-3C, a package substrate 300 with an alternative fluidic path structure is shown, in accordance with an embodiment. Instead of having the vertical and horizontal portions of the fluidic path all in the dummy structure 330, some embodiments may utilize the layer 327 to form the horizontal portions of the fluidic path. That is, a vertical hole 331 may pass through the dummy structure 330 and horizontal channels that are fluidically coupled to the hole 331 can be formed through the layer 327.

Referring now to FIG. 3A, a cross-sectional illustration of a portion of a package substrate 300 is shown, in accordance with an embodiment. In an embodiment, the package substrate 300 is similar to the package substrate 200 in FIG. 2A, with the exception of the dummy structure 330 and the layer 327. For example, the core 305, the component 320, pads 322, cavity 307, fill layer 325, and gap 309 may be similar to corresponding components described in greater detail herein.

However, in FIG. 3A the dummy structure 330 includes a hole 331 that passes entirely through a thickness of the dummy structure 330. As such, fluid above the dummy structure 330 can be fluidically coupled to a bottom of the dummy structure 330. While a single hole 331 is shown, embodiments may also comprise a plurality of holes 331. The use of a single hole 331 (or multiple holes 331 with a single orientation) reduces manufacturing complexity. For example, an injection mold is simplified when molding is used. When machining is used, the drilling process is simplified as well since there is no need for accurate depth control and all drilling is in the same direction.

However, a horizontal path is still needed to flow the fill layer 325 material into the gap 309 between the sidewall of the stack and the sidewall of the cavity 307. This horizontal flow path is provided through the layer 327. For example, portions of the layer 327 may be omitted or removed in order to form channels 329 that extend to the edge of the component 320. In the view of FIG. 3A, the channels 329 go into and out of the illustrated plane. In an embodiment, the channels 329 may be fluidically coupled to the hole 331 in the dummy structure 330. The channels 329 may be defined by the layer 327 along sidewalls, and by the dummy structure 330 and the component 320 from above and below.

Referring now to FIG. 3B, a plan view illustration of the dummy structure 330 is shown, in accordance with an embodiment. The dummy structure 330 may be a solid block of material (e.g., any of the dummy structure materials described in greater detail herein) with at least one hole 331 passing through an entire thickness of the dummy structure 330. The hole 331 may be circular or any other suitable shape. In an embodiment, multiple holes 331 may be provided through the dummy structure 330. Though, all holes 331 may have centerlines that are substantially parallel to each other in some embodiments. For example, all holes may start at the top surface 335 and end at a bottom surface (not visible in FIG. 3B). Further, there may not be any openings or holes that pass through the sidewall surfaces 334.

Referring now to FIG. 3C, a plan view illustration of the top of the component 320 with the overlying layer 327 is shown, in accordance with an embodiment. As shown, a plurality of channels 329A-329D may be patterned or otherwise provided into the layer 327. The channels 329 may intersect each other in some embodiments. In other embodiments, the channels 329 may be isolated from each other. The channels 329 start towards a middle of the layer 327 and extend out to an edge of the layer 327.

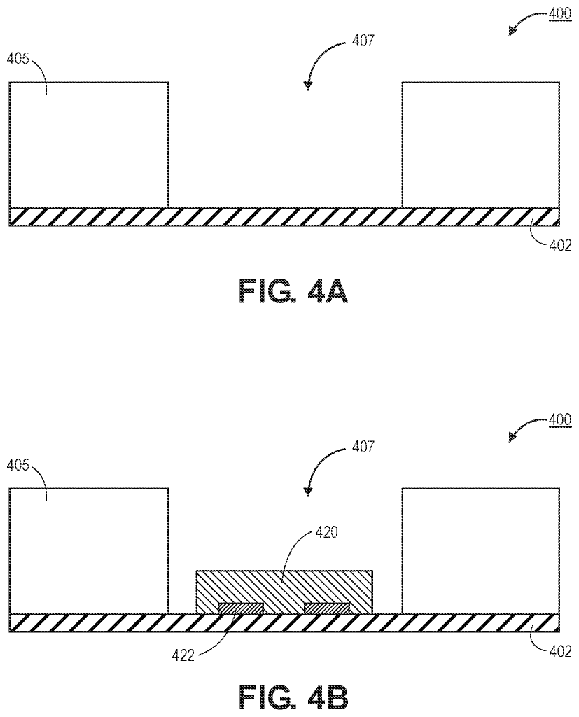

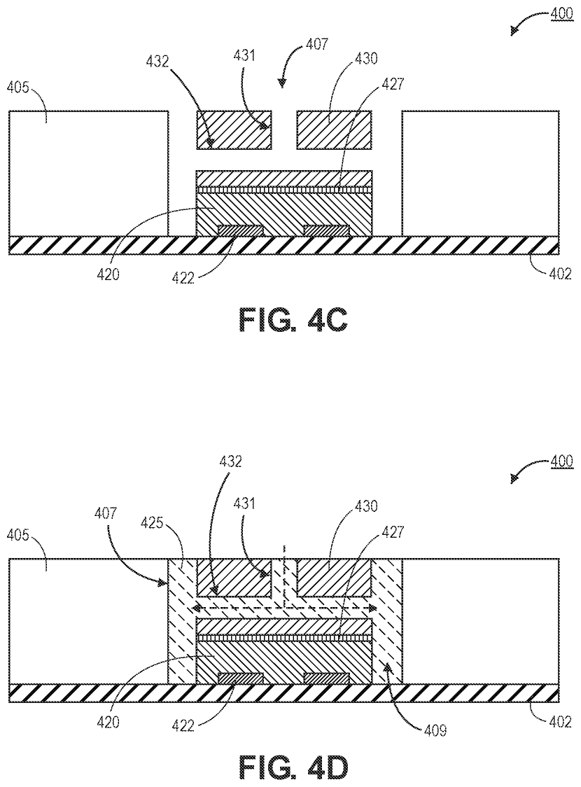

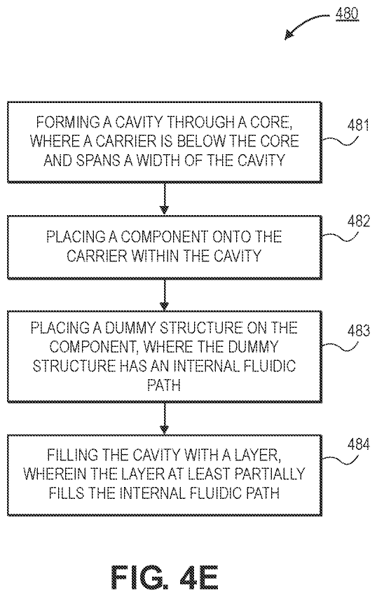

Referring now to FIGS. 4A-4D, a series of cross-sectional illustrations depicting a process for assembling an embedded component 420 in a cavity 407 of a core 405 is shown, in accordance with an embodiment.

Referring now to FIG. 4A, a cross-sectional illustration of a portion of a package substrate 400 at a stage of manufacture is shown, in accordance with an embodiment. In an embodiment, the package substrate 400 may comprise a core 405. The core 405 may be a glass core or an organic core. For example, the core 405 may be similar to any of the cores described in greater detail herein. In an embodiment, a cavity 407 is formed through the core 405. The cavity 407 may be formed with an etching process, a drilling process, a laser ablation process, or any other suitable subtractive process. In the illustrated embodiment, sidewalls of the cavity 407 are vertical. Though, the cavity 407 may have sloped or otherwise tapered sidewalls as well. In an embodiment, a tape 402 or other carrier substrate may be provided along a bottom surface of the core 405. The tape 402 may allow for devices, components, layers, and/or the like to be placed and embedded in the cavity 407.

Referring now to FIG. 4B, a cross-sectional illustration of the portion of the package substrate 400 after a component 420 is placed into the cavity 407 is shown, in accordance with an embodiment. In an embodiment, the component 420 may be placed with a pick-and-place tool, manually placed, or disposed within the cavity 407 with any suitable process. The component 420 may be placed in the cavity 407 so that pads 422 are facing down towards the tape 402. In some instances, the pads 422 may directly contact the tape 402. In an embodiment, the component 420 may be substantially similar to any of the components described in greater detail herein. For example, the component 420 may comprise a passive component (e.g., an inductor, a capacitor, a resistor, or the like). In an embodiment, the component 420 may have a thickness that is smaller than the thickness of the core 405. For example, the component 420 may have a thickness that is up to hundreds of microns smaller than a thickness of the core 405.

Referring now to FIG. 4C, a cross-sectional illustration of the portion of the package substrate 400 after a dummy structure 430 is mounted to the component 420 is shown, in accordance with an embodiment. In an embodiment, the dummy structure 430 is coupled to the component 420 by a layer 427, such as an adhesive layer. In the illustrated embodiment, the component 420 and the dummy structure 430 are separately placed into the cavity 407. However, in other embodiments, the dummy structure 430 may be coupled to the component 420 before both are placed into the cavity 407. Such an embodiment may improve alignment between the component 420 and the dummy structure 430.

In an embodiment, the dummy structure 430 includes an integrated fluidic path. For example, a hole 431 that enters through the top surface of the dummy structure 430 may intersect with openings 432 that extend to sidewall surfaces of the dummy structure 430. As such, fill material can enter from above the stack and be injected into gaps through the side of the dummy structure 430 deeper into the cavity 407. As such, filling of the cavity 407 is improved.

Referring now to FIG. 4D, a cross-sectional illustration of the portion of the package substrate 400 after the fill layer 425 is inserted into the cavity 407 is shown, in accordance with an embodiment. The fill layer 425 may be an underfill material, a molding material, an epoxy, or the like. The fill layer 425 may embed the component 420 and the dummy structure 430. For example, fill layer 425 may substantially fill the gaps 409 between sidewalls of the cavity 407 and the sidewalls of the component 420 and sidewalls of the dummy structure 430. As indicated by the arrows, the fill layer 425 may pass through the hole 431 and be diverted out the sidewalls of the dummy structure 430 by openings 432. After the fill layer 425 is set or otherwise cured, the fill layer 425 may persist in the hole 431 and the openings 432.

In FIGS. 4A-4D, a dummy structure 430 similar to the dummy structure 230 in FIG. 2A is shown as one example. However, a similar process flow may be used in order to form a component 420 and dummy structure 430 stack that uses any dummy structure configuration described herein. For example, the dummy structure 430 may include a hole 431 through an entire thickness of the dummy structure 430, and lateral channels may be formed in the layer 427 (e.g., similar to the embodiment shown in FIG. 3A).

Referring now to FIG. 4E, a process flow diagram depicting a process 480 for assembling a core with a component 420 and a dummy structure 430 in a cavity 407 is shown, in accordance with an embodiment. In an embodiment, the process 480 may begin with operation 481, which comprises forming a cavity 407 through a core 405, where a carrier (or tape) 402 is below the core 405 and spans a width of the cavity 407. In an embodiment, operation 481 may be similar to the structure and process shown in FIG. 4A described above.

In an embodiment, the process 480 may continue with operation 482, which comprises placing a component 420 onto the carrier 402 within the cavity 407. In an embodiment, operation 482 may be similar to the structure and process shown in FIG. 4B described above.

In an embodiment, the process 480 may continue with operation 483, which comprises placing a dummy structure 430 on the component 420, where the dummy structure 430 has an internal fluidic path 431/432. In an embodiment, operation 483 may be similar to the structure and process shown in FIG. 4C described above.

In an embodiment, the process 480 may continue with operation 484, which comprises filling the cavity 407 with a layer 425, wherein the layer at least partially fills the internal fluidic path 431/432. In an embodiment, operation 484 may be similar to the structure and process shown in FIG. 4D described above.

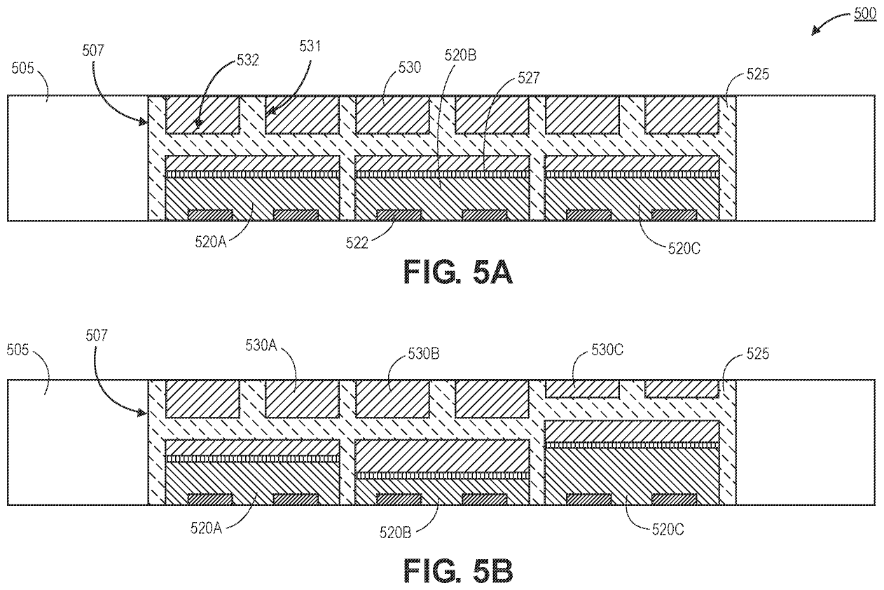

Referring now to FIGS. 5A and 5B, cross-sectional illustrations depicting alternative embodiments are shown. For example, the cavities 507 in FIGS. 5A and 5B are sized to accommodate multiple components 520.

Referring now to FIG. 5A, a cross-sectional illustration of a portion of a package substrate 500 is shown, in accordance with an embodiment. The package substrate 500 may comprise a core 505 that is similar to any of the cores described herein. A cavity 507 may be provided through a thickness of the core 505. In an embodiment, a plurality of components 520 may be placed in the cavity 507. For example, three components 520A-520C are provided in FIG. 5A. Each component 520 may have pads 522 that are substantially coplanar with a bottom surface of the core 505. The components 520 may be similar to any of the components described herein.

In order to match the thickness of the core 505, a dummy structure 530 is coupled to each component 520 by a layer 527 (e.g., an adhesive). The dummy structures 530 may include fluidic paths. For example, the fluidic path may comprise a hole 531 into the top surface of the dummy structure 530 and openings 532 that exit out the sidewalls of the dummy structure 530. This fluidic path allows for improved filling of the fill layer 525 in the remainder of the cavity 507.

Referring now to FIG. 5B, a cross-sectional illustration of a portion of a package substrate 500 is shown, in accordance with an additional embodiment. The package substrate 500 in FIG. 5B is similar to the package substrate 500 in FIG. 5A, with the exception of the components 520A-520C. Instead of being uniform in thickness, the components 520A-520C have different thicknesses. For example, component 520B is the thinnest, and component 520C is the thickest. The different thicknesses may also result in the dummy structures 530A-530C being different from each other to accommodate the different thicknesses. For example, thinner components 520B may have thicker dummy structures 530B, and thicker components 520C may have thinner dummy structures 530C.

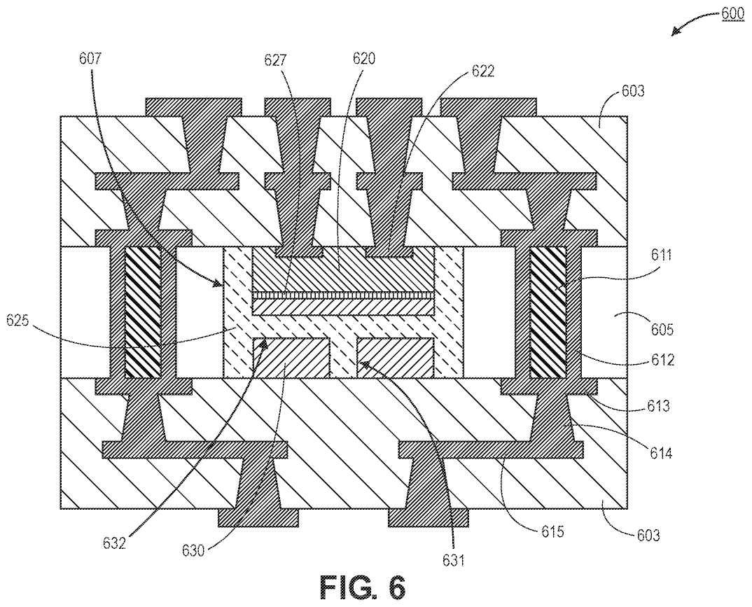

In the embodiments described above, the core layer of the package substrates are highlighted since the components are embedded in the core. However, it is to be appreciated that routing and buildup layers will typically be provided over and/or under the core. An example of such an embodiment is shown in FIG. 6.

Referring now to FIG. 6, a cross-sectional illustration of a portion of a package substrate 600 is shown, in accordance with an embodiment. As shown, a core 605 is sandwiched between a buildup layers 603. The buildup layers 603 may comprise organic dielectric materials that are laminated over each other. For example, buildup film may be used for the buildup layers 603. Electrical routing (e.g., pads 613, vias 614, traces 615, or the like) may be embedded within the buildup layers 603. In an embodiment, through core vias 612 may pass through a thickness of the core 605. The through core vias 612 may be electrically conductive shells that are filled with an insulating core 611. Though, in other embodiments, the through core vias 612 may be fully filled with electrically conductive material.

In an embodiment, a component 620 may be embedded in the core 605. The component 620 may be a passive component similar to passive components described herein. The component 620 may be set in a cavity 607 that passes through the core 605. The component 620 may have pads 622 for connecting to other devices. In order to match the thickness of the core 605, a dummy structure 630 is coupled to the component 620 by a layer 627. The dummy structure 630 may include fluidic paths that route fill layer 625 along the sidewalls of the component 620 and the dummy structure 630. For example, the fluidic paths may comprise a vertical hole 631 and horizontal openings 632. The fluidic path may be at least partially filled by the solid fill layer 625 after the embedding process. While one dummy structure 630 architecture is shown in FIG. 6, it is to be appreciated that any dummy structure architecture described herein may be used in the package substrate 600.

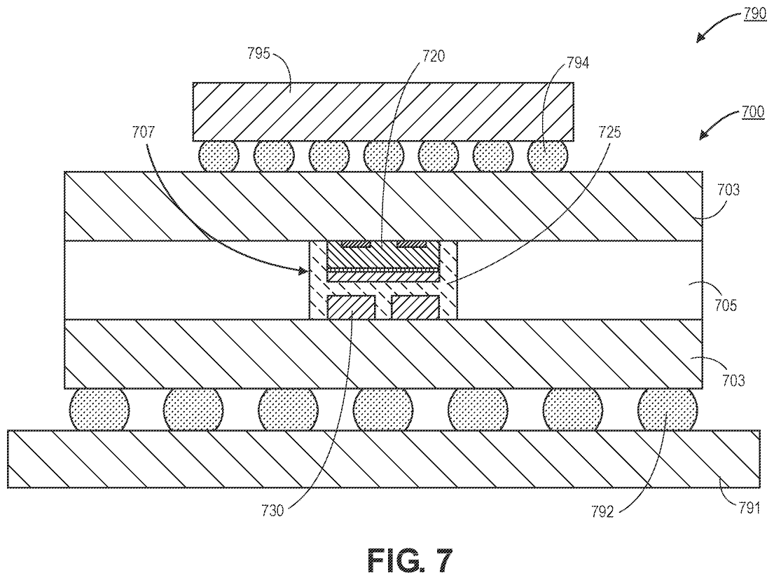

Referring now to FIG. 7, a cross-sectional illustration of an electronic system 790 is shown, in accordance with an embodiment. The electronic system 790 may comprise a board 791, such as a printed circuit board (PCB), a motherboard, or the like. In an embodiment, the board 791 is coupled to a package substrate 700 by interconnects 792. The interconnects 792 may be any second level interconnect (SLI) architecture, such as solder balls, sockets, pins, or the like.

In an embodiment, the package substrate 700 may be similar to any of the package substrates described in greater detail herein. For example, the package substrate 700 may comprise a core 705 with buildup layers 703 over and under the core 705. A cavity 707 through the core 705 may be filled by a component 720 and a dummy structure 730. Fill layer 725 may surround the component 720 and the dummy structure 730. Additionally, the fill layer 725 may fill channels within the dummy structure 730.

In an embodiment, one or more dies 795 are coupled to the package substrate 700 through interconnects 794. The interconnects 704 may comprise any first level interconnect (FLI) architecture, such as solder balls, copper bumps, hybrid bonding interfaces, or the like.

In an embodiment, the dies 795 may be any type of die. For example, the dies 795 may comprise a central processing unit (CPU), a graphics processing unit (GPU), an XPU, a communications die, a memory die, an application specific integrated circuit (ASIC), a field programmable gate array (FPGA), or the like. In an embodiment, the component 720 embedded in the core 705 is electrically coupled to the die 795. The component 720 improves power delivery performance of the die 795.

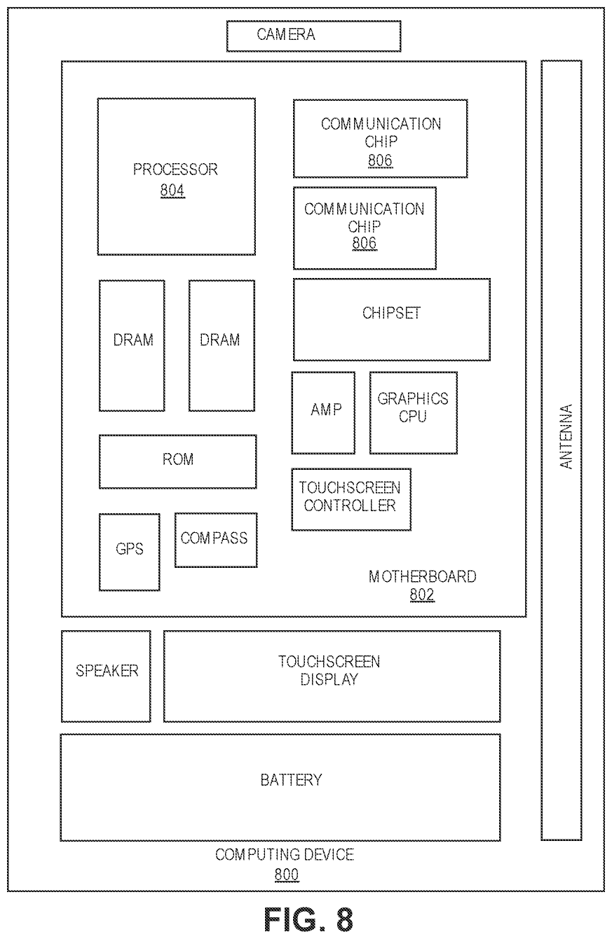

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a component coupled to a dummy structure for matching a thickness of the core, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a component coupled to a dummy structure for matching a thickness of the core, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first component with a first surface and a second surface opposite from the first surface, wherein a pad is provided on the first surface; a layer over the second surface of the first component; and a second component over the layer, wherein the second component comprises a hole that passes through at least a partial thickness of the second component.

Example 2: the apparatus of Example 1, wherein the second component further comprises: an opening that intersects the hole, wherein the opening and the hole are formed on different surfaces of the second component.

Example 3: the apparatus of Example 2, wherein a plurality of openings intersect the hole.

Example 4: the apparatus of Example 2 or Example 3, wherein the opening is formed into a sidewall surface of the second component.

Example 5: the apparatus of Examples 1-4, wherein the hole passes entirely through a thickness of the second component.

Example 6: the apparatus of Example 5, wherein the layer comprises a channel that extends to at least one edge of the layer.

Example 7: the apparatus of Examples 1-6, wherein the first component is an inductor, a capacitor, or a resistor.

Example 8: the apparatus of Examples 1-7, wherein the second component comprises a dielectric material.

Example 9: the apparatus of Example 8, wherein the dielectric material is an epoxy material.

Example 10: the apparatus of Examples 1-9, wherein a thickness of the apparatus is approximately 1 mm or greater.

Example 11: an apparatus, comprising: a core, wherein a cavity is provided into a surface of the core; a first component in the cavity; a first layer over the first component, wherein the first layer comprises an adhesive material; a second component over the first layer, wherein the second component comprises a fluidic path with a first end at a surface of the second component that faces away from the first layer and a second end at a sidewall of the second component; and a second layer that fills at least a portion of the cavity, wherein the second layer is in the fluidic path and between a sidewall of the cavity and sidewalls of the first component and the second component.

Example 12: the apparatus of Example 11, wherein the core comprises a glass layer with a rectangular prism form factor.

Example 13: the apparatus of Example 11 or Example 12, wherein the core comprises an organic layer with embedded fibers.

Example 14: the apparatus of Examples 11-13, wherein the fluidic path has a vertical portion with a centerline that is substantially orthogonal to the surface of the second component and a horizontal portion with a centerline that is substantially orthogonal to the sidewall of the second component.

Example 15: the apparatus of Examples 11-14, wherein a combined thickness of the first component, the first layer, and the second component is substantially equal to a thickness of the core.

Example 16: the apparatus of Examples 11-15, wherein a distance between the sidewall of the cavity and the sidewall of the first component is approximately 50 μm or less.

Example 17: the apparatus of Examples 11-16, wherein the first component comprises an inductor, a capacitor, or a resistor.

Example 18: an apparatus, comprising: a board; a package substrate coupled to the board, wherein the package substrate comprises: a core; and a component embedded in the core, wherein the component is coupled to a dummy feature with a hole through at least a partial thickness of the dummy feature, and wherein the hole is at least partially filled with a material that has a different composition than the dummy feature; and a die coupled to the package substrate.

Example 19: the apparatus of Example 18, wherein a combined height of the component and the dummy feature is substantially equal to a height of the core.

Example 20: the apparatus of Example 18 or Example 19, wherein the apparatus is part of a personal computer, a server, a mobile device, a tablet, or an automobile.

What is claimed is:

1. An apparatus, comprising:
a first component with a first surface and a second surface opposite from the first surface, wherein a pad is provided on the first surface;
a layer over the second surface of the first component; and
a second component over the layer, wherein the second component comprises a hole that passes through at least a partial thickness of the second component.

2. The apparatus of claim 1, wherein the second component further comprises:
an opening that intersects the hole, wherein the opening and the hole are formed on different surfaces of the second component.

3. The apparatus of claim 2, wherein a plurality of openings intersect the hole.

4. The apparatus of claim 2, wherein the opening is formed into a sidewall surface of the second component.

5. The apparatus of claim 1, wherein the hole passes entirely through a thickness of the second component.

6. The apparatus of claim 5, wherein the layer comprises a channel that extends to at least one edge of the layer.

7. The apparatus of claim 1, wherein the first component is an inductor, a capacitor, or a resistor.

8. The apparatus of claim 1, wherein the second component comprises a dielectric material.

9. The apparatus of claim 8, wherein the dielectric material is an epoxy material.

10. The apparatus of claim 1, wherein a thickness of the apparatus is approximately 1 mm or greater.

11. An apparatus, comprising:
a core, wherein a cavity is provided into a surface of the core;
a first component in the cavity;
a first layer over the first component, wherein the first layer comprises an adhesive material;
a second component over the first layer, wherein the second component comprises a fluidic path with a first end at a surface of the second component that faces away from the first layer and a second end at a sidewall of the second component; and
a second layer that fills at least a portion of the cavity, wherein the second layer is in the fluidic path and between a sidewall of the cavity and sidewalls of the first component and the second component.

12. The apparatus of claim 11, wherein the core comprises a glass layer with a rectangular prism form factor.

13. The apparatus of claim 11, wherein the core comprises an organic layer with embedded fibers.

14. The apparatus of claim 11, wherein the fluidic path has a vertical portion with a centerline that is substantially orthogonal to the surface of the second component and a horizontal portion with a centerline that is substantially orthogonal to the sidewall of the second component.

15. The apparatus of claim 11, wherein a combined thickness of the first component, the first layer, and the second component is substantially equal to a thickness of the core.

16. The apparatus of claim 11, wherein a distance between the sidewall of the cavity and the sidewall of the first component is approximately 50 μm or less.

17. The apparatus of claim 11, wherein the first component comprises an inductor, a capacitor, or a resistor.

18. An apparatus, comprising:
a board;
a package substrate coupled to the board, wherein the package substrate comprises:
a core; and
a component embedded in the core, wherein the component is coupled to a dummy feature with a hole through at least a partial thickness of the dummy feature, and wherein the hole is at least partially filled with a material that has a different composition than the dummy feature; and
a die coupled to the package substrate.

19. The apparatus of claim 18, wherein a combined height of the component and the dummy feature is substantially equal to a height of the core.

20. The apparatus of claim 18, wherein the apparatus is part of a personal computer, a server, a mobile device, a tablet, or an automobile.
